(19) United States
(12) Patent Application Publication
(10) Pub. No.: US 2026/0282353 A1
(43) Pub. Date: Sep. 17, 2026

(54) SEMICONDUCTOR MEMORY DEVICE AND METHOD OF MANUFACTURING THE SAME

(71) Applicant: Kioxia Corporation, Tokyo (JP)

(72) Inventors: Shumpei IWAI, Yokkaichi (JP); Naomi FUKUMAKI, Yokkaichi (JP)

(73) Assignee: Kioxia Corporation, Tokyo (JP)

(21) Appl. No.: 19/329,814

(22) Filed: Sep. 16, 2025

(30) Foreign Application Priority Data
Mar. 14, 2025 (JP) 2025-041166

(51) Int. Cl. H10B 43/27; H10B 43/35

(52) U.S. Cl. CPC H10B 43/27; H10B 43/35

(57) ABSTRACT

A memory includes a stacked body in which conductive layers and first insulating layers are alternately stacked in a first direction. A columnar body includes a semiconductor layer extending in the first direction within the stacked body. A second insulating layer is provided on an inner wall of a slit penetrating the stacked body and extending in the second direction. A first nucleation layer is provided inside the second insulating layer in the slit. A second nucleation layer is provided inside the first nucleation layer in the slit. A film formation inhibition layer is provided inside the second nucleation layer in the slit or hole. A conductive material is embedded inside the film formation inhibition layer in the slit. The second nucleation layer has a longer film formation time, which is for growing the conductive material having an identical film thickness, than the first nucleation layer.

### CROSS-REFERENCE TO RELATED APPLICATION

This application is based upon and claims the benefit of priority from Japanese Patent Application No. 2025-041166, filed Mar. 14, 2025, the entire contents of which are incorporated herein by reference.

### FIELD

Embodiments described herein relate generally to a semiconductor memory device and a method of manufacturing the same.

### BACKGROUND

Semiconductor memory devices such as NAND flash memories each may have a three-dimensional memory cell array in which a plurality of memory cells are three-dimensionally arranged. In such a memory cell array, slits are formed to divide a stacked body of the memory cell array into a plurality of parts or holes are formed to penetrate the stacked body. If an aspect ratio of the slit or the hole is large, seams and voids are likely to remain in the material that fills the slit or the hole. Such seams or voids lower reliability of the memory cell array.

### DESCRIPTION OF THE DRAWINGS

FIG. 1 is a cross-sectional view illustrating an example of a configuration of a semiconductor memory device according to an embodiment.

FIG. 2 is a plan view illustrating a stacked body.

FIG. 3 is a cross-sectional view of memory cells each having a three-dimensional structure.

FIG. 4 is a cross-sectional view of the memory cell having the three-dimensional structure.

FIG. 5 is a cross-sectional view illustrating an example of a configuration of columnar bodies and slits according to the present embodiment.

FIG. 6 is a graph showing incubation times of respective conductive layers of first and second nucleation layers.

FIG. 7 is a cross-sectional view illustrating a structure used in this simulation.

FIG. 8 is a cross-sectional view illustrating an example of a method of manufacturing the semiconductor memory device according to the present embodiment.

FIG. 9 is a cross-sectional view illustrating an example of the method of manufacturing the semiconductor memory device subsequent to FIG. 8.

FIG. 10 is a cross-sectional view illustrating an example of the method of manufacturing the semiconductor memory device subsequent to FIG. 9.

FIG. 11 is a cross-sectional view illustrating an example of a deposition process of the conductive layer subsequent to FIG. 10.

FIG. 12 is a cross-sectional view illustrating an example of the deposition process of the conductive layer subsequent to FIG. 11.

FIG. 13 is a cross-sectional view illustrating an example of the deposition process of the conductive layer subsequent to FIG. 12.

### DETAILED DESCRIPTION

Embodiments provide a semiconductor memory device and a method of manufacturing the same capable of inhibiting seams or voids from being formed in slits or holes of a memory cell array.

In general, according to one embodiment, a semiconductor memory device includes a first stacked body in which a plurality of first conductive layers and a plurality of first insulating layers are alternately stacked one layer at a time in a first direction. A columnar body includes a semiconductor layer extending in the first direction within the first stacked body. A second insulating layer is provided on an inner wall of a slit penetrating the first stacked body in the first direction and extending in a second direction intersecting with the first direction, or is provided on an inner wall of a hole penetrating an interlayer insulating film around the first stacked body in the first direction. A first nucleation layer is provided inside the second insulating layer in the slit or hole. A second nucleation layer is provided inside the first nucleation layer in the slit or hole. A film formation inhibition layer is provided inside the second nucleation layer in the slit or hole. A conductive material is embedded inside the film formation inhibition layer in the slit or hole. The second nucleation layer has a longer film formation time, which is for growing the conductive material having the same film thickness, than the first nucleation layer.

Hereinafter, embodiments of the present disclosure will be described, with reference to the accompanying drawings. The present embodiments do not limit the present disclosure. The drawings are schematic or conceptual. In the specification and the drawings, the same elements are represented by the same reference numerals and signs.

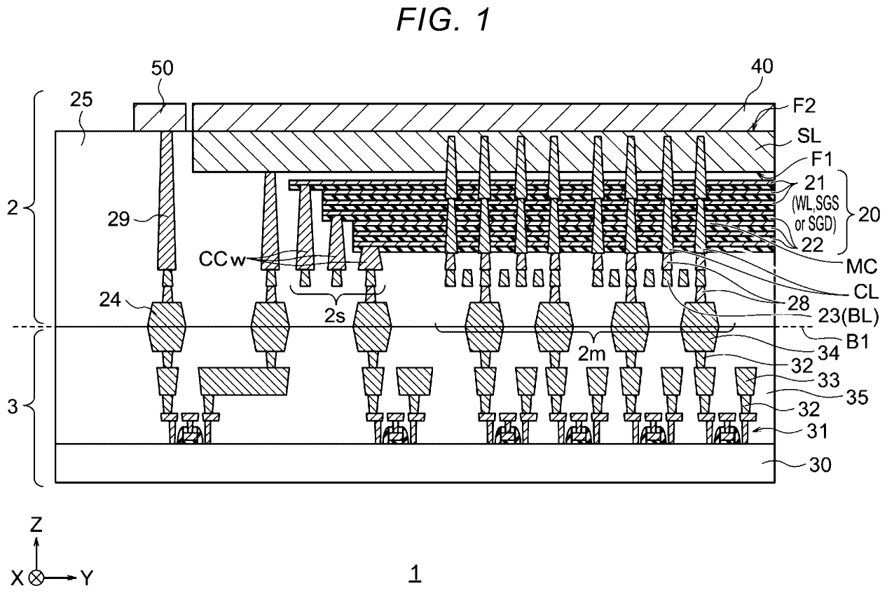

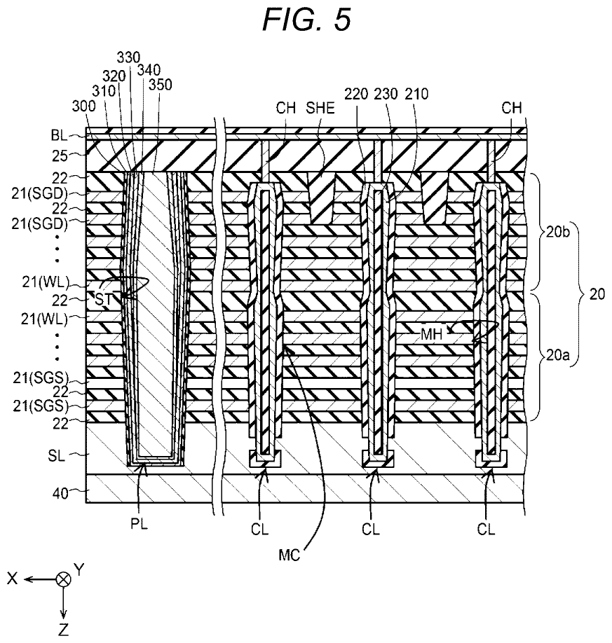

FIG. 1 is a cross-sectional view illustrating an example of a configuration of a semiconductor memory device 1 according to the present embodiment. Hereinafter, a stacking direction of a stacked body 20 is defined as the Z direction. A direction that intersects with the Z direction, for example, a direction perpendicular to the Z direction is defined as the Y direction. A direction that intersects with each of the Z direction and the Y direction, for example, a direction perpendicular to each of the Z direction and the Y direction is defined as the X direction. FIG. 1 shows semiconductor memory device 1 assuming that the +Z direction is an upward direction. In the cross-sectional views of FIG. 5 and subsequent figures, an array chip is shown assuming that the −Z direction is the upward direction. It is noted that, in the present specification, the ±Z direction is an example of the first direction, and the ±Y direction is an example of the second direction.

The semiconductor memory device 1 includes an array chip 2 having a memory cell array, and a CMOS chip 3 having a complementary metal oxide semiconductor (CMOS) circuit. The array chip 2 and the CMOS chip 3 are bonded at a bonding surface B1, and are electrically connected to each other through wiring bonded at the bonding surface B1. FIG. 1 shows a state where the array chip 2 is provided on the CMOS chip 3.

The CMOS chip 3 includes a substrate 30, transistors 31, vias 32, wirings 33 and 34, and an interlayer insulating film 35.

The substrate 30 is, for example, a semiconductor substrate such as a silicon substrate. The transistor 31 is an N-type MOS field effect transistor (MOSFET) or a P-type MOSFET provided on the substrate 30. The transistor 31 is configured as, for example, a CMOS circuit that controls a memory cell array 2m of the array chip 2. The plurality of transistors 31 are configured as logic circuits such as a sense amplifier, a row decoder, and a column decoder. Semiconductor elements such as resistance element and capacitive element other than the transistors 31 may be formed on the substrate 30.

The vias 32 electrically connect the transistors 31 to the wiring 33, or the wiring 33 to the wiring 34. The wirings 33 and 34 are configured as a multilayer wiring structure in the interlayer insulating film 35. The wiring 34 is embedded in the interlayer insulating film 35 and is exposed to be coplanar with the surface of the interlayer insulating film 35. The wirings 33 and 34 are electrically connected to the transistors 31 and the like. The vias 32 and the wirings 33 and 34 each employ, for example, a metal such as copper or tungsten. The interlayer insulating film 35 covers and protects the transistors 31, the vias 32, and the wirings 33 and 34. The interlayer insulating film 35 employs, for example, an insulating film made of silicon oxide or the like.

The array chip 2 includes the stacked body 20, a columnar body CL, a source layer SL, a metal layer 40, contact plugs CCw, a contact plug 29, a bonding pad 50, wirings 23 and 24, vias 28, and an interlayer insulating film 25.

The stacked body 20 is provided above the transistor 31 and is located to be away from the substrate 30 in the +Z direction. The stacked body 20 is formed by alternately stacking the plurality of electrode films 21 and the plurality of insulating films 22 one layer at a time along the Z direction. The stacked body 20 and the columnar bodies CL are configured as the memory cell array. The electrode film 21 employs, for example, a conductive metal such as molybdenum or tungsten. The insulating film 22 employs, for example, silicon oxide. The insulating films 22 insulate the electrode films 21 from each other. That is, the plurality of electrode films 21 are stacked in an insulated state from each other. The number of stacked electrode films 21 and the number of stacked insulating films 22 each are optional. The insulating film 22 may be, for example, a porous insulating film or an air gap.

One or more electrode films 21 at each of the upper end and the lower end of the stacked body 20 in the Z direction function as each of the source-side select gate SGS and the drain-side select gate SGD. The electrode film 21 between the source-side select gate SGS and the drain-side select gate SGD functions as the word line WL. The word line WL is a gate electrode of the memory cell MC. The source-side select gate SGS is a gate electrode of the source-side select transistor. The drain-side select gate SGD is the gate electrode of the drain-side select transistor. The source-side select gate SGS is provided in an upper region of the stacked body 20. The drain-side select gate SGD is provided in a lower region of the stacked body 20. The upper region refers to a region of the stacked body 20 farther from the CMOS chip 3 (closer to the metal layer 40), and the lower region refers to a region of the stacked body 20 closer to the CMOS chip 3.

The semiconductor memory device 1 has a plurality of memory cells MC connected in series between a source-side select transistor and a drain-side select transistor. A structure, in which the source-side select transistor, the memory cells MC, and the drain-side select transistor are connected in series, is referred to as a “memory string” or a “NAND string”. For example, the memory string is connected to the bit line BL through the via 28. The bit line BL is the wiring 23 that is provided under the stacked body 20 and extends in the X direction. Therefore, hereinafter, the bit line BL is also referred to as a bit line 23.

The stacked body 20 includes the plurality of columnar bodies CL. The columnar bodies CL are provided in the stacked body 20, extend through the stacked body 20 in the stacking direction (Z direction) of the stacked body 20, and are provided in a range from the vias 28, which are connected to the bit lines 23, to the source layer SL. An internal structure of the columnar bodies CL will be described later. It is noted that FIG. 1 shows a case where the columnar bodies CL are formed in two stages in the Z direction. However, the columnar body CL may be formed to be divided into three or more stages.

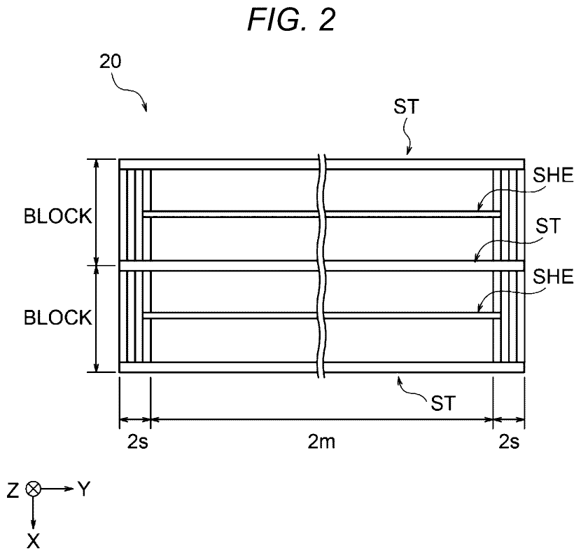

Further, a plurality of slits ST (refer to FIGS. 2 and 5) are provided in the stacked body 20. The slits ST extend in the Y direction and penetrate the stacked body 20 in the stacking direction (Z direction) of the stacked body 20. An insulating film made of silicon oxide or the like and a conductor are embedded in the slits ST, and are each configured in a plate shape in each slit ST. The inner wall of the slit ST is covered with the insulating film, and a conductive material is embedded inside the insulating film. The slits ST electrically divide the electrode film 21 of the stacked body 20. The conductive material may function as a source wiring that reaches the source layer SL.

The source layer SL is provided on the stacked body 20. The source layer SL corresponds to the stacked body 20. The stacked body 20 (memory cell array 2m) is provided on a side of a face F1 of the source layer SL, and a metal layer 40 is provided on a side of a face F2 opposite to the face F1. The source layer SL is connected in common to one end of the plurality of columnar bodies CL, and applies a common source voltage to the plurality of columnar bodies CL in the same memory cell array 2m. That is, the source layer SL functions as a common source electrode of the memory cell array 2m. The source layer SL employs, for example, a conductive material such as doped polysilicon. The metal layer 40 employs, for example, a metal material having a lower resistance than the source layer SL, such as copper, aluminum, molybdenum, or tungsten.

Meanwhile, the bonding pad 50 is provided above the surface F2 of the source layer SL in a region in which the source layer SL is not provided. The bonding pad 50 is connected to a metal wire or the like (not illustrated in the drawing) and is supplied with electric power or receives a signal, from the outside of the semiconductor memory device 1. The bonding pad 50 is connected to one end of the contact plug 29 in the Z direction. The bonding pad 50 is connected to the transistors 31 of the CMOS chip 3 through the contact plug 29, the wiring 24, and the wiring 34. The external power supply supplied from the bonding pad 50 is supplied to the transistors 31. Alternatively, a signal is supplied to the transistor 31 through the bonding pad 50.

The contact plugs CCw are provided in a peripheral portion of the stacked body 20 and extend in the Z direction in the interlayer insulating film 25. The contact plugs CCw are electrically connected between the electrode film 21 (word line WL) and the wiring 24. The contact plugs CCw are provided in a staircase portion 2s in which the electrode films 21 are formed in a staircase shape at the end of the stacked body 20, and are electrically connected to the electrode films 21. The contact plug CCw is provided to transmit the word line voltage from the CMOS chip 3 to each electrode film 21. The contact plug CCw employs, for example, a metal such as copper or tungsten.

The contact plug 29 is provided on a peripheral portion of the stacked body 20 and extends in the Z direction in the interlayer insulating film 25. The contact plug 29 is provided to range at least from the lower side of the stacked body 20 to the upper side of the stacked body 20.

The contact plug 29 is electrically connected between the bonding pad 50 and the wiring 24. The contact plug 29 is used to supply power or signals from the bonding pad 50 to the array chip 2 or the CMOS chip 3. The contact plug 29 employs, for example, a metal such as copper or tungsten. The power supply employs, for example, a power supply voltage VDD or a reference voltage (for example, a ground voltage) VSS lower than the power supply voltage VDD. The signal may be a control signal from the outside, or may be write data or read data.

In the present embodiment, the array chip 2 and the CMOS chip 3 are separately formed and are bonded to each other on the bonding surface B1. Therefore, the array chip 2 does not include the transistors 31. Further, the CMOS chip 3 does not include the stacked body 20 (memory cell array 2m).

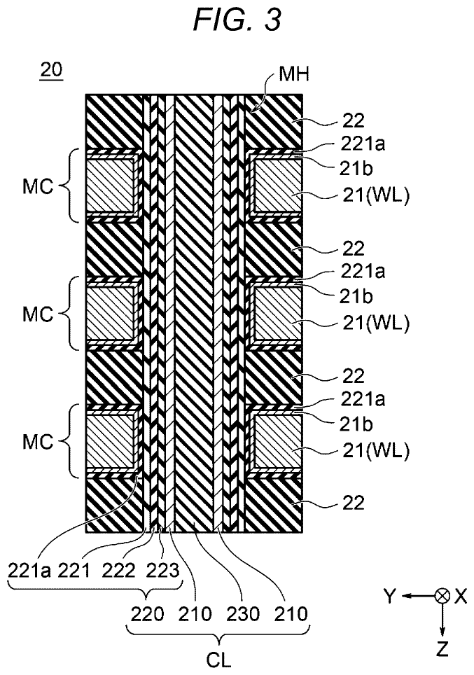

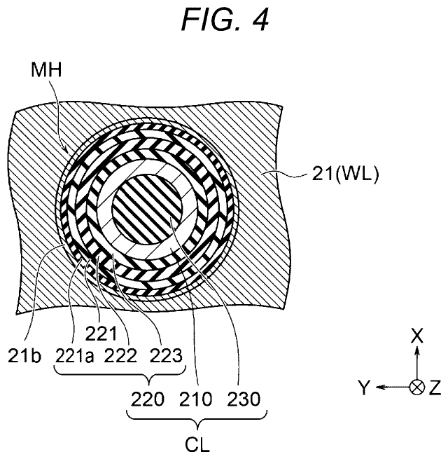

The vias 28, the wiring 23, and the wiring 24 are provided under the stacked body 20. The wirings 23 and 24 are embedded in the interlayer insulating film 25. The wiring 24 is exposed to be coplanar with the surface of the interlayer insulating film 25. The wirings 23 and 24 are electrically connected to the semiconductor bodies (210 in FIGS. 3 and 4) of the columnar bodies CL, and the like. The via 28, the wiring 23, and the wiring 24 each employ, for example, a metal such as copper or tungsten. The interlayer insulating film 25 covers and protects the stacked body 20, the vias 28, the wiring 23, and the wiring 24. The interlayer insulating film 25 employs, for example, an insulating film made of silicon oxide or the like.

The interlayer insulating film 25 and the interlayer insulating film 35 are bonded to each other on the bonding surface B1. Accordingly, the wiring 24 and the wiring 34 are bonded to each other on the bonding surface B1 so as to be substantially coplanar. Thereby, the array chip 2 and the CMOS chip 3 are electrically connected to each other through the wiring 24 and the wiring 34.

FIG. 2 is a plan view illustrating the stacked body 20. The stacked body 20 includes the staircase portion 2s and the memory cell array 2m. The staircase portion 2s is provided, for example, at the end of the stacked body 20. The memory cell array 2m is interposed between or surrounded by the staircase portions 2s. The slits ST are provided from the staircase portion 2s at one end of the stacked body 20 through the memory cell array 2m to the staircase portion 2s at the other end of the stacked body 20. The slits SHE are provided at least in the memory cell array 2m. The slit SHE is thinner in the Z direction than the slit ST and extends substantially parallel to the slit ST. The slits SHE electrically divide the electrode film 21 on the lower region side of the stacked body 20 for each drain-side select gate SGD. The slit SHE employs, for example, an insulating film made of silicon oxide or the like. Further, the slit ST may include a source wiring electrically connected to the source layer SL while being electrically separated from the electrode films 21 of the stacked body 20.

A part of the stacked body 20 interposed between the two slits ST illustrated in FIG. 2 is referred to as a block (BLOCK). The block is configured as, for example, a minimum unit of data erasing. The slits SHE are provided in the block. The stacked body 20 between the slit ST and the slit SHE is referred to as a finger. The drain-side select gate SGD is separated for each finger. Therefore, at the time of writing and reading data, one finger in the block can be selected through the drain-side select gate SGD. The finger is configured as the minimum unit for writing and reading data.

Each of FIGS. 3 and 4 is a cross-sectional view illustrating a memory cell having a three-dimensional structure. The plurality of columnar bodies CL are provided in memory holes MH in the stacked body 20. Each columnar body CL penetrates the stacked body 20 from one end of the stacked body 20 along the Z direction, and is provided to range from the inner side of the stacked body 20 to the inner side of the source layer SL. Each of the plurality of columnar bodies CL includes a semiconductor body 210, a memory film 220, and a core layer 230. The columnar body CL includes the core layer 230 that is provided at the center thereof, the semiconductor body (semiconductor layer) 210 that is provided around the core layer 230, and the memory film 220 that is provided around the semiconductor body 210. The semiconductor body 210 extends in the stacking direction (Z direction) in the stacked body 20. The semiconductor body 210 is electrically connected to the source layer SL. The memory film 220 is provided between the semiconductor body 210 and the electrode film 21, and has a charge trapping portion. The plurality of columnar bodies CL selected one by one from each finger are connected in common to one bit line 23 through the vias 28 in FIG. 1. Each of the columnar bodies CL is provided, for example, in the region of the memory cell array 2m.

As illustrated in FIG. 4, a shape of the memory hole MH in the X-Y plane is, for example, a circle or an ellipse. A block insulating film 221a forming a part of the memory film 220 may be provided between the electrode film 21 and the insulating film 22. The block insulating film 221a is made of, for example, silicon oxide or metal oxide. One example of the metal oxide is aluminum oxide. A barrier film 21b may be provided between the electrode film 21 and the insulating film 22 and between the electrode film 21 and the memory film 220. When the electrode film 21 is made of, for example, tungsten, the barrier film 21b is made of, for example, titanium nitride. The block insulating film 221a prevents back tunneling of charges from the electrode film 21 to the memory film 220. The barrier film 21b improves adhesion between the electrode film 21 and the block insulating film 221a.

The semiconductor body 210 has, for example, a cylindrical shape having a bottom. The semiconductor body 210 employs, for example, polysilicon. The semiconductor body 210 may employ, for example, undoped silicon. Further, the semiconductor body 210 may employ p-type silicon. The semiconductor body 210 is formed as channels of the drain-side select transistor, the memory cell MC, and the source-side select transistor. That is, the plurality of memory cells MC each have a storage area between the semiconductor body 210 and the electrode film 21 formed as the word line WL, and are stacked in the Z direction. One end of the plurality of semiconductor bodies 210 in the same memory cell array 2m is electrically connected in common to the source layer SL.

The memory film 220 includes, for example, a cover insulating film 221, a charge trapping film 222, a tunnel insulating film 223, and a block insulating film 221a. The memory film 220 is provided between the inner wall of the memory hole MH and the semiconductor body 210 except for the block insulating film 221a. A shape of the memory film 220 is, for example, cylindrical. The charge trapping film 222 and the tunnel insulating film 223 each extend in the Z direction.

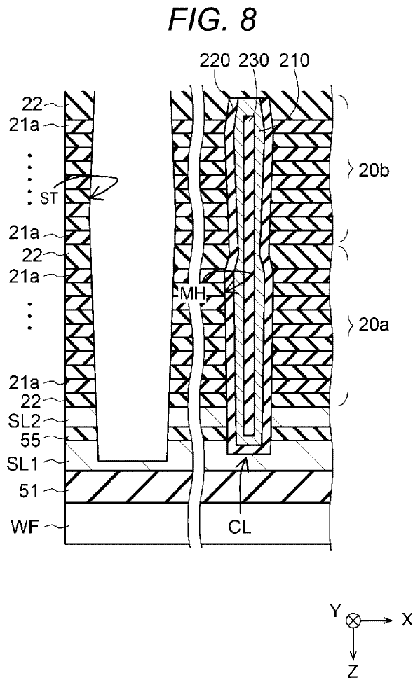

The cover insulating film 221 is provided between the insulating film 22 and the charge trapping film 222 and between the block insulating film 221a and the charge trapping film 222. The cover insulating film 221 contains, for example, silicon oxide. The cover insulating film 221 protects the charge trapping film 222 from being etched when the sacrificial film (21a of FIG. 8) is replaced with the electrode film 21 (replacement process).

The charge trapping film 222 is provided between the cover insulating film 221 and the tunnel insulating film 223. The charge trapping film 222 contains, for example, silicon nitride, and has trap sites in which charges are trapped in the film. A part of the charge trapping film 222 interposed between the electrode film 21, which serves as the word line WL, and the semiconductor body 210 forms a storage area of the memory cell MC as the charge trapping portion. A threshold voltage of the memory cell MC changes depending on presence or absence of charge in the charge trapping portion or the amount of charge trapped in the charge trapping portion. Thereby, the memory cell MC stores information.

The tunnel insulating film 223 is provided between the semiconductor body 210 and the charge trapping film 222. The tunnel insulating film 223 contains, for example, silicon oxide or silicon oxide and silicon nitride. The tunnel insulating film 223 is a potential barrier between the semiconductor body 210 and the charge trapping film 222. For example, when electrons are injected from the semiconductor body 210 to the charge trapping film 222 (write operation), and when holes are injected from the semiconductor body 210 to the charge trapping film 222 (erae operation), the electrons and the holes pass through (tunneling) the potential barrier of the tunnel insulating film 223.

The core layer 230 fills the internal space of the cylindrical semiconductor body 210. The core layer 230 has, for example, a columnar shape. The core layer 230 contains, for example, silicon oxide and is insulating.

FIG. 5 is a cross-sectional view illustrating an example of a configuration of the columnar bodies and slits according to the present embodiment. FIG. 5 shows the columnar bodies CL and the slits ST assuming that the −Z direction is the upward direction. In addition, FIG. 5 shows a configuration of the plate PL in the slit ST. The configuration can be applied to a configuration of the contact plugs CCw and 29 in the contact holes, although the length and size thereof in the Y direction are different. Hereinafter, the configuration of the plate PL will be described, and the description of the configuration of the contact plugs CCw and 29 will not be repeated.

The stacked body 20 includes a plurality of stacked portions 20a and 20b. The stacked portion 20b is provided above the stacked portion 20a (in the −Z direction). Each of the plurality of stacked portions 20a and 20b is configured with the plurality of electrode films 21 and the plurality of insulating films 22 alternately stacked one layer at a time in the −Z direction.

The semiconductor bodies 210 of the plurality of columnar bodies CL extend in the Z direction in the stacked body 20 and penetrate the stacked body 20 so as to reach the source layer SL. The semiconductor bodies 210 of the columnar bodies CL are electrically connected to the bit line BL at an upper end on the −Z side through via contacts CH. The semiconductor body 210 is directly connected to the source layer SL at a sidewall of the lower end on the +Z side.

The memory holes MH of the columnar bodies CL are formed separately in each of the stacked portions 20a and 20b. Therefore, an area of the columnar body CL on the X-Y plane decreases toward the +Z direction in the stacked portion 20b. That is, the columnar body CL has a tapered shape toward the +Z direction in the stacked portion 20b. The area of the columnar body CL on the X-Y plane is smallest between the stacked portion 20a and the stacked portion 20b. The area of the columnar body CL on the X-Y plane increases once at the end of the stacked portion 20a in the −Z direction, and then decreases again toward the +Z direction. That is, the columnar body CL has a taper on a side surface thereof to have a tapered shape toward the +Z direction in the stacked portions 20a and 20b. Further, the stacked portion 20 includes two stacked portions 20a and 20b, but may include one or three or more stacked portions. In such a case, the memory holes MH are also formed corresponding to the stacked portions. Therefore, the columnar body CL has a taper on the side surface thereof to have a tapered shape for each stacked portion.

The slits ST penetrate the stacked body 20 in the Z direction and extend in the Y direction. The plate-shaped plate PL is provided in each slit ST. The plate PL is embedded in the slit ST and penetrates the stacked body 20 in the Z direction together with the slit ST and extends in the Y direction. An aspect ratio of the slit ST increases as the number of stacked layers of the electrode film 21 and the insulating film 22 increases and thus the height of the stacked body 20 in the Z direction increases. In FIG. 5, one slit ST is formed to penetrate two stacked portions 20a and 20b of the stacked body 20 at once. However, like the memory hole MH, two slits ST may be formed to penetrate each of the two stacked portions 20a and 20b. In such a case, an area of the slit ST on the X-Y plane also decreases in the +Z direction in the stacked portion 20b, increases once between the stacked portion 20a and the stacked portion 20b, and decreases again in the +Z direction in the stacked portion 20a. That is, the columnar body CL has a taper on a side surface thereof to have a tapered shape toward the +Z direction in each of the stacked portions 20a and 20b.

The plate PL includes an insulating layer 300, a barrier layer 310, a first nucleation layer 320, a second nucleation layer 330, a film formation inhibition layer 340, and a conductive layer 350. The plate PL is provided inside the slit ST, and therefore has a taper on the side surface thereof like the slit ST.

The insulating layer 300 covers the inner wall of the slit ST, and electrically separates the layers 310 to 350 of the other plate PL inside the insulating layer 300 from the electrode film 21. For example, the insulating layer 300 employs, for example, an insulating material such as silicon oxide. The insulating layer 300 is provided on the side surface of the slit ST, and may not be provided on the bottom surface of the slit ST. In such a case, the layers 310 to 350 of the other plate PL inside the insulating layer 300 of the plate PL can be electrically connected to the source layer SL while being electrically separated from the electrode film 21.

The barrier layer 310 covers an inner side of the insulating layer 300 in the slit ST. The barrier layer 310 may be made of, for example, titanium (Ti) or titanium nitride (TiN), or may be a stacked film thereof. The barrier layer 310 inhibits diffusion of the metal material such as the plate PL into the stacked body 20.

The first nucleation layer 320 covers the inner sides of the insulating layer 300 and the barrier layer 310 in the slit ST. The first nucleation layer 320 employs, for example, a metal material containing silicon, and more specifically, may employ tungsten (WSi) containing silicon. The first nucleation layer 320 promotes growth of the conductive layer 350.

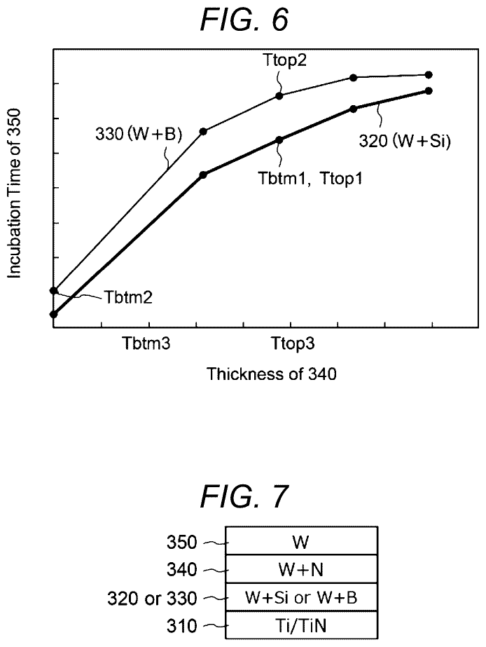

The first nucleation layer 320 is formed on the side and bottom surfaces of the slit ST. As illustrated in FIG. 6, assuming that a film thickness of the first nucleation layer 320 at the opening of the slit ST is Ttop1 and a film thickness of the first nucleation layer 320 at the bottom portion of the slit ST is Tbtm1, Tbtm1/Ttop1 is 0.7 or more. That is, the first nucleation layer 320 is provided conformally in the slit ST with a thickness that is nearly uniform.

The second nucleation layer 330 covers an inner side of the first nucleation layer 320 in the slit ST. The second nucleation layer 330 employs, for example, a metal material containing boron (B), and more specifically, may employ tungsten (WB) containing boron (B). The second nucleation layer 330 promotes the growth of the conductive layer 350. However, the second nucleation layer 330 has a longer film formation time, which is for growing the conductive layer 350 having the same film thickness, than the first nucleation layer 320. That is, the second nucleation layer 330 has a longer incubation time for the conductive layer 350 than the first nucleation layer 320. The incubation time for the conductive layer 350 will be described later with reference to FIG. 6.

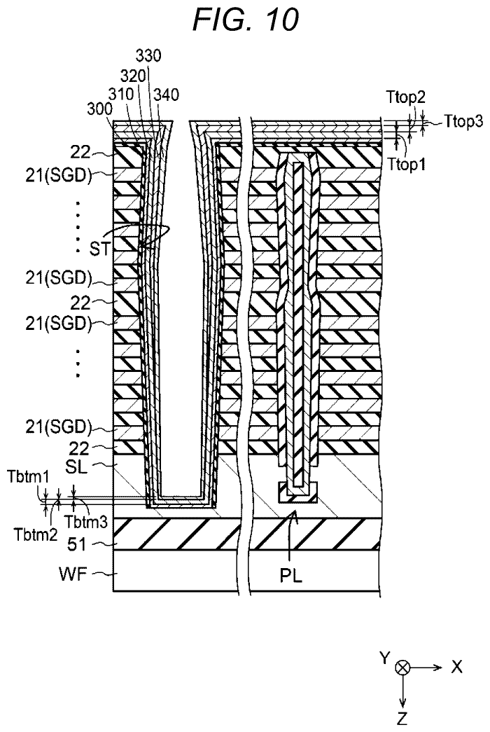

The second nucleation layer 330 is thick at the opening of the slit ST and is provided on the upper portion of the side surface of the slit ST. The second nucleation layer 330 becomes thinner toward the bottom portion, and is hardly provided on the bottom surface of the slit ST. As illustrated in FIG. 10, assuming that a film thickness of the second nucleation layer 330 at the opening of the slit ST is Ttop2 and a film thickness of the second nucleation layer 330 at the bottom portion of the slit ST is Tbtm2, Tbtm2/Ttop2 is 0.3 or less.

The film formation inhibition layer 340 covers the inner side of the second nucleation layer 330 in the slit ST. The film formation inhibition layer 340 employs, for example, a metal material containing nitrogen (N), and more specifically, may employ tungsten (WN) containing nitrogen (N). The film formation inhibition layer 340 inhibits the growth of the conductive layer 350 compared to the first nucleation layers 320 and the second nucleation layers 330. That is, unlike the first nucleation layers 320 and the second nucleation layers 330, the film formation inhibition layer 340 has a considerably long incubation time for the conductive layer 350, and the conductive layer 350 is less likely to grow. Therefore, the film formation inhibition layer 340 functions as a film that inhibits the growth of the conductive layer 350.

The film formation inhibition layer 340 is provided to range from the opening of the side surface of the slit ST to the bottom surface thereof. The film formation inhibition layer 340 is thick at the opening of the slit ST and becomes thinner toward the bottom portion. That is, the thickness of the film formation inhibition layer 340 is thicker at the opening of the slit ST than at the bottom portion thereof. Assuming that a film thickness of the film formation inhibition layer 340 at the opening of the slit ST is Ttop3 and a film thickness of the film formation inhibition layer 340 at the bottom portion of the slit ST is Tbtm3, Tbtm3/Ttop3 is 0.1 or less. Ttop3 is, for example, 2 nm or less.

The conductive layer 350 is embedded inside the film formation inhibition layer 340 in the slit ST. The conductive layer 350 employs, for example, a metal material such as tungsten.

As described above, in the present embodiment, a stacked film including the first nucleation layer 320, the second nucleation layer 330, and the film formation inhibition layer 340 is provided between the inner wall of the slit ST and the conductive layer 350. The first nucleation layer 320 is provided conformally at the bottom portion and opening of the slit ST. On the other hand, the second nucleation layer 330 on the first nucleation layer 320 is provided relatively thick at the opening of the slit ST. The second nucleation layer 330 is provided relatively thin or not provided at the bottom portion of the slit ST. The film formation inhibition layer 340 on the second nucleation layer 330 is also provided relatively thick at the opening of the slit ST. The film formation inhibition layer 340 is provided relatively thin or not provided at the bottom portion of the slit ST. By providing such a stacked film including the first nucleation layer 320, the second nucleation layer 330, and the film formation inhibition layer 340 in the slit ST, it is possible to prevent seams or voids from occurring in the conductive layer 350 in the slit ST, as described later.

Next, the incubation time for the conductive layer 350 will be described.

FIG. 6 is a graph showing the incubation time for the conductive layer 350 for each of the first nucleation layers 320 and the second nucleation layers 330. The horizontal axis indicates the film thickness of the film formation inhibition layer 340 formed on the first nucleation layer 320 or the second nucleation layer 330. The vertical axis indicates the incubation time for the conductive layer 350 (for example, tungsten).

FIG. 7 is a cross-sectional view illustrating a structure used in this simulation. In this simulation, either the first nucleation layer 320 or the second nucleation layer 330 is formed on the barrier layer 310, and the film formation inhibition layer 340 and the conductive layer 350 are formed thereon. In such a case, the film thicknesses of the first nucleation layer 320 and the second nucleation layer 330 are all constant (for example, 8 nm).

The incubation time is a time required to generate a deposition material by reducing the material gas in the deposition process. Therefore, if the incubation time is long, it takes a long time to reduce the material gas, and the material is deposited relatively thinly per unit time, or is not deposited at all. If the incubation time is short, the reduction of the material gas is completed within a short time, and the material is deposited relatively thickly per unit time.

As illustrated in FIG. 6, regardless of whether the film formation inhibition layer 340 is formed on the first nucleation layer 320 or the second nucleation layer 330, the incubation time for the conductive layer 350 becomes longer as the thickness of the film formation inhibition layer 340 increases. Therefore, the incubation time for the conductive layer 350 is short and the conductive layer 350 is easily formed, at the bottom portion of the slit ST where the thickness (for example, Tbtm3) of the film formation inhibition layer 340 is relatively small. That is, a deposition rate of the conductive layer 350 is relatively fast, at the bottom portion of the slit ST. In contrast, the incubation time for the conductive layer 350 is long and it is difficult to form the conductive layer 350, at the opening of the slit ST where the thickness (for example, Ttop3) of the film formation inhibition layer 340 is relatively thick. That is, the deposition rate of the conductive layer 350 is relatively slow, at the opening of the slit ST.

As illustrated in FIG. 6, the incubation time for the conductive layer 350 when the conductive layer 350 is formed on the second nucleation layer 330 with the film formation inhibition layer 340 interposed therebetween is longer than the incubation time therefor when the conductive layer 350 is formed on the first nucleation layer 320 with the film formation inhibition layer 340 interposed therebetween. That is, the conductive layer 350 is easily formed when the first nucleation layer 320 and the film formation inhibition layer 340 are used as a base, and the deposition rate of the conductive layer 350 is relatively high. In contrast, it is difficult to form the conductive layer 350 when the second nucleation layer 330 and the film formation inhibition layer 340 are used as the base, and the deposition rate of the conductive layer 350 is relatively low.

As described with reference to FIG. 5, the first nucleation layer 320 is conformally formed in the slit ST. On the other hand, the second nucleation layer 330 is thick at the opening of the slit ST and is thinner toward the bottom portion, or is not formed at the bottom portion. By depositing the conductive layer 350 on the film formation inhibition layer 340 on such a stacked film including the first nucleation layers 320 and the second nucleation layers 330, the conductive layer 350 is easily deposited at the bottom portion of the slit ST and is less likely to be deposited thereon at a position closer to the opening. That is, by using a difference in incubation time for the conductive layer 350 in the film formation inhibition layer 340 on the first nucleation layers 320 and the second nucleation layers 330, the conductive layer 350 is deposited to range from the bottom portion of the slit ST toward the opening. Thereby, in the present embodiment, it is possible to inhibit seams or voids from being formed in the slit ST.

Next, a method of manufacturing the semiconductor memory device 1 according to the present embodiment will be described.

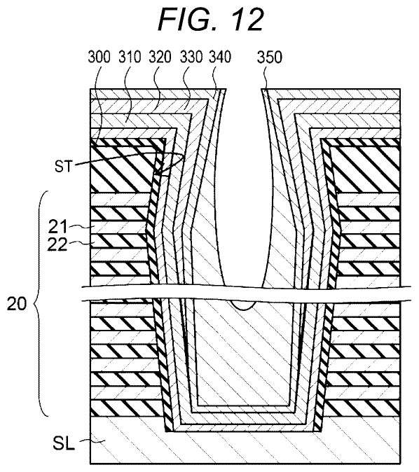

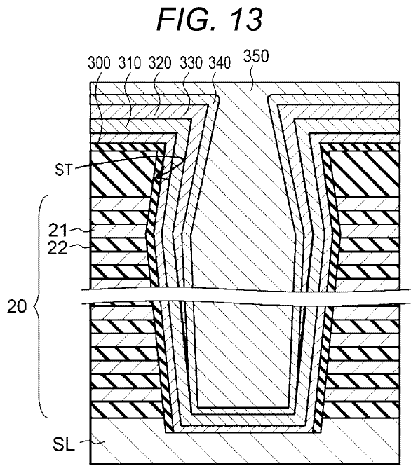

FIGS. 8 to 13 are cross-sectional views each illustrating an example of a method of manufacturing a semiconductor memory device according to the present embodiment. For convenience of description, FIGS. 8 to 10 show that the columnar body CL and the slit ST are arranged one by one.

First, as illustrated in FIG. 8, an insulating layer 51, a material layer SL1 for the source layer SL, a sacrifice layer 55, and a material layer SL2 for the source layer SL are deposited on a semiconductor wafer WF in this order. The semiconductor wafer WF may be, for example, a silicon substrate. The insulating layer 51 employs, for example, an insulating material such as silicon oxide. The material layers SL1 and SL2 each employ, for example, a conductive material such as doped polysilicon. The sacrifice layer 55 employs, for example, a stacked film including silicon oxide, silicon nitride, and silicon oxide.

Next, a stacked portion 20a is formed by alternately stacking the plurality of insulating films 22 and the plurality of sacrificial films 21a one layer at a time on the material layer SL2. The insulating film 22 employs, for example, an insulating material such as silicon oxide. The sacrificial film 21a employs, for example, a material having etching selectivity to the insulating film 22, such as silicon nitride. Next, a memory hole MH penetrating the stacked portion 20a is formed, and a sacrificial material (not illustrated) is embedded in the memory hole.

Next, the stacked portion 20b is formed by alternately stacking the plurality of insulating films 22 and the plurality of sacrificial films 21a one layer at a time on the stacked portion 20a. Next, the memory hole MH penetrating the stacked portion 20b is formed, and is connected to the memory hole MH of the stacked portion 20a. The sacrificial material in the memory hole MH of the stacked portion 20a is removed through the memory hole MH of the stacked portion 20b. Thereby, a memory hole MH is formed which is connected to the stacked portions 20a and 20b. The columnar body CL is formed by forming a memory film 220, a semiconductor body 210, and a core layer 230 in the memory hole MH.

Next, the slit ST penetrating the stacked body 20 in the Z direction and extending in the Y direction is formed by using lithography and etching techniques. Thereby, the structure illustrated in FIG. 8 is obtained. The slit ST may be formed separately in each of the stacked portions 20a and 20b. In such a case, similar to the memory hole MH, the slit ST is formed in the stacked portion 20a, and then a sacrificial material (not illustrated) is embedded therein. After the stacked portion 20b is formed, the slit ST may be formed in the stacked portion 20b, and the sacrificial material may be removed.

Next, the sacrifice layer 55 is selectively removed through the slit ST to expose the memory film 220 at the lower portion the columnar body CL. Further, the memory film 220 exposed through the slit ST is removed to expose the semiconductor body 210. Next, the semiconductor body 210 is electrically connected to the source layer SL by embedding a conductive material in the space where the sacrifice layer 55 was present.

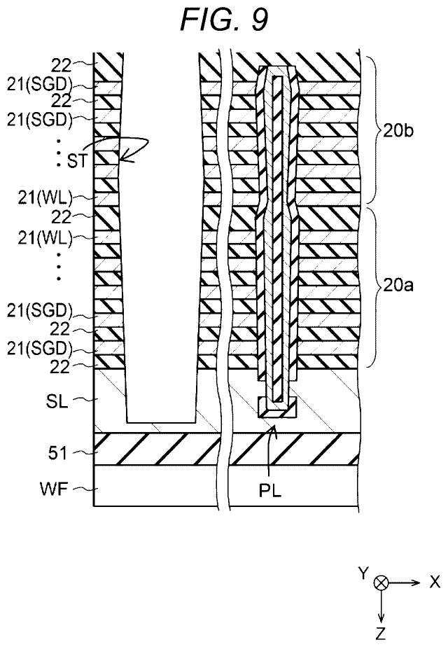

Then, the sacrificial film 21a is removed through the slit ST, and the material of the electrode film 21 (for example, tungsten or molybdenum) is embedded in the space where the sacrificial film 21a was present. Thereby, the sacrificial film 21a of the stacked body 20 is replaced with the electrode film 21 (replacement process). Through the replacement process, as illustrated in FIG. 9, the stacked body 20 including the electrode film 21 and the insulating film 22 is formed.

Next, as illustrated in FIG. 10, the insulating layer 300 and the barrier layer 310 are formed in the slit ST in this order. The insulating layer 300 and the barrier layer 310 cover the inner surface of the slit ST. The insulating layer 300 employs, for example, an insulating material such as silicon oxide. The barrier layer 310 employs, for example, one of titanium and titanium nitride or a stacked film thereof.

Then, the first nucleation layer 320 is formed on the insulating layer 300 and the barrier layer 310 in the slit ST. The first nucleation layer 320 is made of, for example, tungsten formed by adding silane (SiH₄) as a reducing gas to a material gas (tungsten fluoride: WF₆). Such tungsten contains a lot of silicon and has a relatively high resistance. However, the first nucleation layer 320 is able to promote deposition of the second nucleation layer 330, the film formation inhibition layer 340, and the conductive layer 350 formed thereafter, and is able to improve adhesion of the second nucleation layer 330, the film formation inhibition layer 340, and the conductive layer 350 to the first nucleation layer 320.

The first nucleation layer 320 is formed on the side and bottom surfaces of the slit ST, for example, by using the atomic layer deposition (ALD) method. In the ALD method, tungsten fluoride as a material gas and silane as a reducing gas are alternately supplied. In the silicon supply process of the first nucleation layer 320, a partial pressure of silane (SiH₄) is about 6%, a partial pressure of argon (Ar) is about 19%, a partial pressure of nitrogen (N₂) is about 0%, and a partial pressure of hydrogen (H₂) is about 75%. It is noted that the supply of tungsten fluoride is not described here.

The partial pressure of silane (SiH₄) as a reducing gas is relatively high at about 6%. Thus, the first nucleation layer 320 is formed relatively conformally with a certain degree of uniform thickness on the side and bottom surfaces of the slit ST. A ratio (Tbtm1/Ttop1) of the film thickness Tbtm1 at the bottom portion of the slit ST to the film thickness Ttop1 at the opening of the slit ST is 0.7 or more.

Next, the second nucleation layer 330 is formed on the first nucleation layer 320 in the slit ST. The second nucleation layer 330 is made of, for example, tungsten formed by adding diborane (B₂H₆) as a reducing gas to a material gas (tungsten fluoride: WF₆). Such tungsten contains a lot of boron and has a relatively high resistance. However, the second nucleation layer 330 is able to promote the deposition of the film formation inhibition layer 340 and the conductive layer 350 formed thereafter, and is able to improve the adhesion of the film formation inhibition layer 340 and the conductive layer 350 to the second nucleation layer 330.

The second nucleation layer 330 is formed on the side surface near the opening of the slit ST by using, for example, the ALD method. In the ALD method, tungsten fluoride as a material gas and diborane as a reducing gas are alternately supplied. In the boron supply process for the second nucleation layer 330, a partial pressure of diborane (B₂H₆) is about 0.3%, the partial pressure of argon (Ar) is about 19%, the partial pressure of nitrogen (N₂) is about 5.7%, and the partial pressure of hydrogen (H₂) is about 75%.

The partial pressure of diborane as a reducing gas is considerably lower than that of silane for the first nucleation layer 320. Therefore, the second nucleation layer 330 is thicker at the opening of the slit ST and thinner at the bottom portion, or is not formed at the bottom portion, compared to the first nucleation layer 320. A ratio (Tbtm2/Ttop2) of the film thickness Ttop2 at the opening of the slit ST to the film thickness Tbtm2 at the bottom portion of the slit ST is 0.3 or less.

Then, the film formation inhibition layer 340 is formed on the second nucleation layer 330 in the slit ST. The film formation inhibition layer 340 is made of, for example, tungsten formed by adding ammonia (NH₃) as a reducing gas to a material gas (tungsten fluoride: WF₆). Such tungsten contains a lot of nitrogen and has a relatively high resistance. In addition, the film formation inhibition layer 340 inhibits the conductive layer 350, which is formed thereafter, from being deposited.

The film formation inhibition layer 340 is formed on the side surface of the slit ST by, for example, using a CVD method. In the CVD method, tungsten fluoride as a material gas and ammonia as a reducing gas are supplied at the same time. In the film formation process of the film formation inhibition layer 340, gas flow rates of tungsten fluoride and ammonia are lowered to make the coverage worse than that of the first nucleation layer 320. For example, the partial pressure of tungsten fluoride is 1%, the partial pressure of ammonia is 0.3%, and the partial pressure of argon is 98.7%. Thereby, tungsten fluoride and ammonia are consumed at the upper portion of the slit ST and scarcely reach the bottom portion. Therefore, the film formation inhibition layer 340 is provided thick at the opening of the slit ST and thin at the bottom portion. A ratio (Tbtm3/Ttop3) of the film thickness Ttop3 at the opening of the slit ST to the film thickness Tbtm3 at the bottom portion of the slit ST is 0.1 or less.

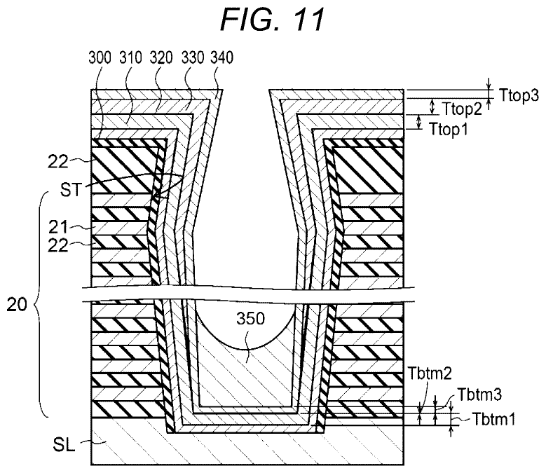

FIGS. 11 to 13 are cross-sectional views each illustrating an example of the deposition process of the conductive layer. As described above, the incubation time for the conductive layer 350 when the conductive layer 350 is formed on the second nucleation layer 330 with the film formation inhibition layer 340 interposed therebetween is longer than the incubation time therefor when the conductive layer 350 is formed on the first nucleation layer 320 with the film formation inhibition layer 340 interposed therebetween. According to the present embodiment, the first nucleation layer 320 is formed conformally in the slit ST, but the film thickness of the second nucleation layer 330 is thick at the opening of the slit ST and is thinner toward the bottom portion. That is, the first nucleation layer 320 is thick at the bottom portion of the slit ST, and the second nucleation layer 330 is thick at the opening of the slit ST. Therefore, the conductive layer 350 is more likely to deposit at the bottom portion of the slit ST than at the opening.

Further, the incubation time for the conductive layer 350 is short, at the bottom portion of the slit ST where the film formation inhibition layer 340 has a relatively thin film thickness (Tbtm3). In contrast, the incubation time for the conductive layer 350 is long, at the opening of the slit ST where the film formation inhibition layer 340 has a relatively thick film thickness (Ttop3). Therefore, from the viewpoint of the film thickness of the film formation inhibition layer 340, the conductive layer 350 is more likely to deposit at the bottom portion of the slit ST than at the opening.

As described above, according to the present embodiment, the incubation time for the conductive layer 350 at the bottom portion and opening of the slit ST can be controlled by using the difference in the incubation time for the conductive layer 350 at the first nucleation layer 320 and the second nucleation layer 330 and further by using the difference in the film thickness of the film formation inhibition layer 340. As a result, as illustrated in FIGS. 11 to 13, the conductive layer 350 can be grown from the bottom portion of the slit ST, and seams and voids inside the conductive layer 350 can be prevented from occurring.

Then, the film formation inhibition layer 340, the first nucleation layer 320 and the second nucleation layer 330, and the barrier layer 310 on the insulating film 22 are removed by using a CMP method or the like. Further, as illustrated in FIG. 5, the interlayer insulating film 25, the bit line BL, the via contact CH, and the like are formed, and the array chip 2 is completed.

The semiconductor memory device 1 is completed by bonding the array chip 2 and the CMOS chip 3.

As described above, according to the present embodiment, the incubation time for the conductive layer 350 can be controlled by adjusting not only the thickness of the film formation inhibition layer 340 but also the thicknesses of the first nucleation layers 320 and the second nucleation layers 330 stacked thereunder. Therefore, as illustrated in FIGS. 11 to 13, the conductive layer 350 can be embedded from the bottom portion of the slit ST. Thereby, it is possible to prevent the seams from being formed in the slit ST.

The above-mentioned embodiment has been described with respect to the slit ST, but the present embodiment can also be applied to the contact holes of the contact plugs CCw and 29. In such a case, in the description of FIG. 5 and subsequent figures, the slit ST can be read as a contact hole. In addition, in such a case, the contact hole is provided to penetrate the interlayer insulating film 25 around the stacked body 20 in the Z direction. The configurations of cross-sections of the contact plugs CCw and 29 may be the same as the configuration of the plate PL in the slit ST in the above-mentioned embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a first stacked body that has a plurality of first conductive layers and a plurality of first insulating layers which are alternately stacked in a first direction;
a columnar body that includes a semiconductor layer extending in the first direction within the first stacked body;
a second insulating layer that is provided on an inner wall of a slit penetrating the first stacked body in the first direction and extending in a second direction intersecting with the first direction;
a first nucleation layer that is provided inside the second insulating layer in the slit;
a second nucleation layer that is provided inside the first nucleation layer in the slit;
a film formation inhibition layer that is provided inside the second nucleation layer in the slit; and
a conductive material that is embedded inside the film formation inhibition layer in the slit,
wherein the second nucleation layer has a longer film formation time, which is for growing the conductive material having an identical film thickness, than the first nucleation layer.

2. The semiconductor memory device according to claim 1, wherein a thickness of the film formation inhibition layer is greater at an opening of the slit than at a bottom portion of the slit.

3. The semiconductor memory device according to claim 1, wherein a thickness of the second nucleation layer is greater at an opening of the slit than at a bottom portion of the slit.

4. The semiconductor memory device according to claim 1, wherein the first nucleation layer includes silicon (Si).

5. The semiconductor memory device according to claim 1, wherein the second nucleation layer includes boron (B).

6. The semiconductor memory device according to claim 1, wherein the conductive material includes nitrogen (N).

7. The semiconductor memory device according to claim 1, wherein each of the first nucleation layer, the second nucleation layer and the conductive material includes tungsten.

8. The semiconductor memory device according to claim 1, wherein a ratio of a film thickness of the first nucleation layer at a bottom portion of the slit to a film thickness of the first nucleation layer at an opening of the slit is 0.7 or more.

9. The semiconductor memory device according to claim 8, wherein a ratio of a film thickness of the second nucleation layer at the bottom portion of the slit to a film thickness of the second nucleation layer at the opening of the slit is 0.3 or less.

10. The semiconductor memory device according to claim 9, wherein a ratio of a film thickness of the film formation inhibition layer at the bottom portion of the slit to a film thickness of the second nucleation layer at the opening of the slit is 0.1 or less.

11. A method of manufacturing a semiconductor memory device, the method comprising:
forming a first stacked body by alternately stacking a plurality of first conductive layers and a plurality of first insulating layers in a first direction;
forming a plurality of first holes penetrating the first stacked body in the first direction;
forming, in the plurality of first holes, a plurality of first columnar bodies including a semiconductor layer, respectively;
forming a slit penetrating the first stacked body in the first direction and extending in a second direction intersecting with the first direction;
forming an insulating layer on an inner wall of the slit;
forming a first nucleation layer, which promotes film formation of a conductive material filling the slit, inside the insulating layer of the slit;
forming a second nucleation layer, which promotes the film formation of the conductive material, inside the first nucleation layer of the slit;
forming a film formation inhibition layer, which inhibits the film formation of the conductive material, inside the second nucleation layer of the slit; and
embedding a conductive material inside the film formation inhibition layer of the slit,
wherein the second nucleation layer has a longer film formation time, which is for growing the conductive material having an identical film thickness, than the first nucleation layer.

12. The method of manufacturing according to claim 11,
forming a second hole penetrating an interlayer insulating film around the first stacked body in the first direction;
forming an other insulating layer on an inner wall of the slit or the second hole;
forming an other first nucleation layer inside the other insulating layer of the second hole;
forming an other second nucleation layer inside the other first nucleation layer of the second hole;
forming an other film formation inhibition layer inside the other second nucleation layer of the second hole; and
embedding an other conductive material inside the other film formation inhibition layer of the second hole.

13. The method of manufacturing according to claim 11, wherein
in the forming of the first nucleation layer, silane (SiH₄) is used as a reducing gas for tungsten fluoride (WF₆), and
in the forming of the second nucleation layer, diborane (B₂H₆) is used as a reducing gas for tungsten fluoride (WF₆).

14. The method of manufacturing according to claim 13, wherein a partial pressure of the diborane used as the reducing gas in the forming of the second nucleation layer is lower than a partial pressure of the silane used as the reducing gas in the forming of the first nucleation layer.

15. The method of manufacturing according to claim 11,
wherein in the forming of the film formation inhibition layer, ammonia (NH₃) is used as a reducing gas for tungsten fluoride (WF₆).

16. The method of manufacturing according to claim 11, wherein the first nucleation layer comprises tungsten containing silicon (WSi).

17. The method of manufacturing according to claim 11, wherein the second nucleation layer comprises tungsten containing boron (WB).

18. The method of manufacturing according to claim 11, wherein the film formation inhibition layer comprises tungsten containing nitrogen (WN).

19. The method of manufacturing according to claim 11, wherein the film formation inhibition layer has a thickness greater at an opening of the slit than at a bottom portion of the slit.

20. The method of manufacturing according to claim 11, wherein the second nucleation layer has a thickness greater at an opening of the slit than at a bottom portion of the slit.
